(19) United States
(12) Patent Application Publication
(10) Pub. No.: US 2004/0045810 A1
(43) Pub. Date: Mar. 11, 2004

(54) Apparatus and method of forming thin film from negatively charged sputtered ions

(75) Inventor: Steven Kim, Harrington Park, NJ (US)

Correspondence Address: MORGAN LEWIS & BOCKIUS LLP, 1111 PENNSYLVANIA AVENUE NW, WASHINGTON, DC, 20004, US

(73) Assignee: Plasmion Corporation

(21) Appl. No.: 10/234,105

(22) Filed: Sep. 5, 2002

(51) Int. Cl. C23C 14/32

(52) U.S. Cl. 204/192.11; 204/298.07; 204/298.04; 204/298.12; 204/298.19

(57) ABSTRACT

The present invention discloses an apparatus and a method of forming a thin film from negatively charged sputtered ions. More specifically, a sputter deposition apparatus for forming a thin film on a substrate includes at least one sputter target comprised of a material for the thin film, an ion gun emitting a neutralized ion beam towards the sputter target, a sputter gas source supplying a sputter gas into the ion gun, and a cesium vapor emitter inducing a plurality of negatively ionized sputtered particles from the sputter target and located in close proximity to the sputter target to introduce cesium vapor onto a reaction surface, wherein the cesium vapor emitter includes a feeding manifold having a plurality of apertures therein, a reservoir coupled to the feeding manifold and filled with a cesium slurry, and an on/off valve controlling an amount of the cesium vapor from the reservoir.

### BACKGROUND OF THE INVENTION

1. Field of the Invention

The present invention relates to a thin film deposition process, and more particularly, to an apparatus and a method of forming a thin film from negatively charged sputtered ions. Although the present invention is suitable for a wide scope of applications, it is particularly suitable for forming a thin film having high density and strong adhesion at a relatively fast sputter rate.

2. Discussion of the Related Art

Sputtering has been widely used to form a thin film on a substrate because it may be one of the preferred methods to meet the strict requirements in commercial markets. Sputtering is generally classified into two types: plasma sputtering and ion beam sputtering.

Plasma sputtering utilizes plasma (i.e., ionized gas) created by an inert gas. When the plasma collides a target containing a source material for a thin film to be formed, particles are sputtered off from the surface of the target. The sputtered particles then travel to the substrate and grow on the substrate as a thin film. In order to intensify the collision between the target and the ionized gas, a magnetic field is generated over the target. This is called magnetron sputtering.

However, both plasma sputtering and magnetron sputtering require a relatively high concentration of gas molecules. Due to relatively high pressure (above 1 mTorr) operation, the sputtered particles are thermalized (i.e., kinetic energy of sputtered particle loses its energy by gas collision).

In ion beam sputtering, a noble gas ion beam is extracted from an ion source and used to bombard a target. A gas plasma is generated by electron collisions inside the source. The ion beam sputtering may be operated at a lower pressure in the order of 10⁻⁴ Torr. Thus, a long mean free path can be obtained so that the particles will not lose its energy by collision before deposition. However, a sputter rate of such conventional ion beam sputtering is very slow, so that it makes the cost per area too expensive for many applications.

### SUMMARY OF THE INVENTION

Accordingly, the present invention is directed to an apparatus and a method of forming a thin film from negatively charged sputtered ions that substantially obviate one or more of problems due to limitations and disadvantages of the related art.

Another object of the present invention is to provide an apparatus and a method of forming a thin film having high density and strong adhesion at a relatively fast sputter rate.

Additional features and advantages of the invention will be set forth in the description, which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a cesium vapor emitter for inducing a plurality of negatively ionized sputtered particles from a sputter target includes a feeding manifold having a plurality of apertures therein and placed in close proximity to the sputter target to introduce cesium vapor onto a reacting surface of the target, a reservoir coupled to the feeding manifold and filled with a cesium slurry, and an on/off valve controlling an amount of the cesium vapor from the reservoir.

In another aspect of the present invention, a sputter deposition apparatus for forming a thin film on a substrate includes at least one sputter target comprised of a material for the thin film, an ion gun emitting a neutralized ion beam towards the sputter target, a sputter gas source supplying a sputter gas into the ion gun, and a cesium vapor emitter inducing a plurality of negatively ionized sputtered particles from the sputter target and located in close proximity to the sputter target to introduce cesium vapor onto a reaction surface, wherein the cesium vapor emitter includes a feeding manifold having a plurality of apertures therein, a reservoir coupled to the feeding manifold and filled with a cesium slurry, and an on/off valve controlling an amount of the cesium vapor from the reservoir.

In another aspect of the present invention, a sputter deposition apparatus for forming a thin film on a substrate includes an anode, at least one sputter target comprised of a material for the thin film, electrically coupled to the anode, wherein the sputter target acts as a cathode and has a hollow region providing a directionality of sputtered particles from the sputter target towards the substrate, a magnetic field source generating a magnetic field around the sputter target, a cesium vapor emitter inducing a plurality of negatively ionized sputtered particles from the sputter target and located in close proximity onto surfaces of the wall in the sputter target to provide cesium vapor, wherein the cesium vapor emitter includes a feeding manifold having a plurality of apertures therein and surrounding the sputter target, a reservoir coupled to the feeding manifold and filled with a cesium slurry, and an on/off valve controlling an amount of the cesium vapor from the reservoir.

In another aspect of the present invention, a method of forming a thin film on a substrate using a negatively ionized sputter beam includes emitting cesium vapor from a cesium vapor emitter onto a sputter target, wherein the cesium vapor emitter includes a cesium feeding manifold located in close proximity to the target and a cesium reservoir filled with a cesium slurry and coupled to the cesium feeding manifold, introducing a sputter gas source into an ion gun facing into the sputter target, producing an ion beam from the ion gun onto the sputter target, initiating a surface ionization with help of cesium on the target, producing a plurality of negatively ionized sputtered particles from the sputter target, and forming the thin film on the substrate by depositing the negatively ionized sputtered particles on the substrate.

In a further aspect of the present invention, a method of forming a thin film on a substrate using a negatively ionized sputter beam includes generating a magnetic field at an inside surface of a hollow region in a sputter target, emitting cesium vapor from a cesium vapor emitter onto the inside surface of the sputter target, wherein the cesium vapor emitter includes a cesium feeding manifold located in close proximity to the target and a cesium reservoir filled with a cesium slurry and coupled to the cesium feeding manifold, creating a potential difference to initiate a surface ionization with help of cesium on the target, producing a plurality of negatively ionized sputtered particles from the sputter target, and forming the thin film on the substrate by depositing the negatively ionized sputtered particles on the substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 is a schematic view of an apparatus for forming a thin film from a negatively charged sputtered ion according to a first embodiment of the present invention;

FIG. 2 is a schematic cross-sectional view of a cesium vapor emitter according to the present invention;

FIG. 3 is a schematic cross-sectional view of an on/off valve in the cesium vapor emitter of FIG. 2;

FIG. 4 is a schematic cross-sectional view of on/off valves connected in parallel; and

FIG. 5 is a schematic cross-sectional view of a sputter target of an apparatus for forming a thin film from a negatively charged sputtered ion according to a second embodiment of the present invention.

### DETAILED DESCRIPTION OF THE ILLUSTRATED EMBODIMENTS

Reference will now be made in detail to the illustrated embodiments of the present invention, examples of which are illustrated in the accompanying drawings. Wherever possible, the same reference numbers will be used throughout the drawings to refer to the same or like parts.

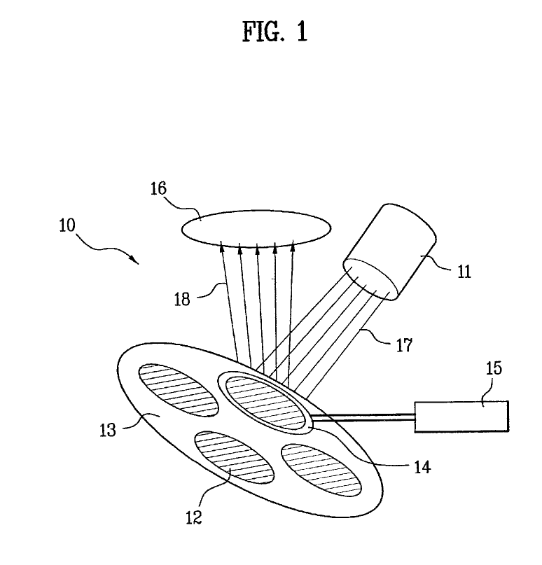

FIG. 1 is a schematic view of an apparatus 10 for forming a thin film on a substrate from negatively charged sputtered ions according to a first embodiment of the present invention.

An ion beam source 11 is used for sputtering off the target material by an ion beam. The ion beam is generated in the ion beam source 11 by ionizing an inert gas, such as argon, provided into the ion beam source 11. Some of the generated ions are accelerated and extracted by a series of grids. After extraction, the positively charged ion beam is generated. The positively charged ion beam is neutralized by a negatively charged electron emitter (i.e., neutralizer), so that a neutralized ion beam is emitted from the ion beam onto a sputter target 12 mounted on a substrate holder 13.

A simple stage holder may be used for holding a single sputter target. Alternatively, if a plurality of source materials are necessary for forming a thin film, a rotating substrate holder for accommodating the sputter targets as shown in FIG. 1 may be used for forming a thin film having various compositions.

Generally, neutral sputtered particles and a small amount of positively ionized particles are sputtered from the sputter target 12. In order to generate negatively sputtered particles from the sputter target, cesium is provided onto the surface of the sputter target. As well known, cesium is the most effective element in reducing the work function of the surface. Thus, it facilitates to emit negative ions from the surface in sputtering.

A cesium vapor emitter is installed in the apparatus, as shown in FIG. 1. The cesium vapor emitter includes a feeding manifold 14 and a cesium reservoir 15.

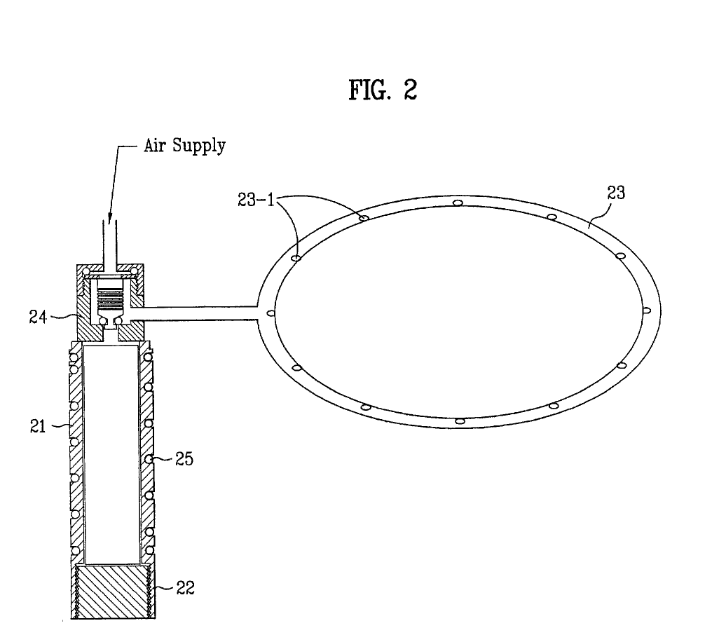

More specifically, FIG. 2 illustrates a schematic cross-sectional view of the cesium vapor emitter of FIG. 1. A cesium reservoir 21 is filled with a replaceable cesium cartridge 22 having cesium slurry, known as Cemite. The cesium slurry is a mixture of cesium mordenite powder and liquid cesium. For example, portions of the cesium modernite powder and liquid cesium in the mixture may be in the range of about 20 to 80% and about 80 to 20%, respectively. Cesium mordenite is a synthetic Zeolite™ having a composition of Cs₂O.Al₂O₃.10SiO₂. For more emission of cesium vapor, the cesium vapor emitter may be heated at a temperature of about 50 to 300° C. by a heater 25 surrounding the cesium reservoir 21. An amount of cesium vapor may also be controlled by an on/off valve 24.

The cesium vapor is then distributed on the reacting surface of the sputter target though a feeding manifold 23. For a better efficiency in generating the negatively charged sputtered ions, the feeding manifold 23 may have to match the shape of the sputter target. There are many apertures 23-1 formed in the feeding manifold 23 for emitting the cesium vapor onto the surface of the sputter target.

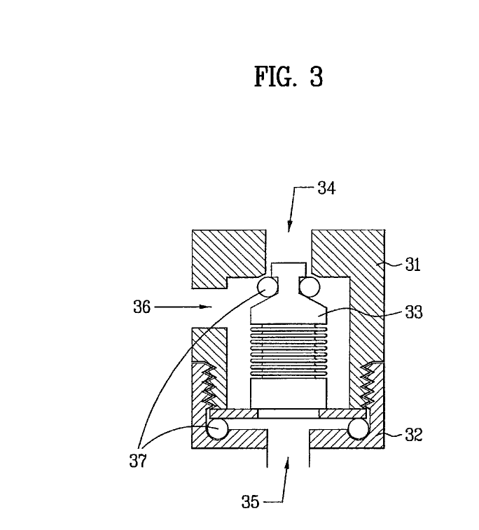

FIG. 3 is a schematic cross-sectional view of an on/off valve in the cesium vapor emitter of FIG. 2. The on/off valve includes a bottom part 31, a cover part 32, a bellow 33, and an O-ring 37. An amount of the cesium vapor to the feeding manifold 23 is controlled by amounts of the cesium vapor through gas inlets 34 and 35. The cesium vapor is introduced through the gas inlet 34 while a pressured air is injected through the air inlet 35. Thus, an amount of the cesium vapor emitted through a gas outlet 36 is controlled by the bellow 33 closing or opening the path between the gas inlet 34 and the gas outlet 36. The O-ring 37 improves the sealings in the cesium vapor emitter.

The on/off valve is used for both the deposition control and the system maintenance. For example, for a multi-layer coating, a cesium reservoir for deposition is open and the others are closed. For the maintenance, the process chamber may have to be exposed to the atmospheric pressure. This causes to contaminate the cesium reservoir. The on/off valve protects the cesium reservoir for the maintenance.

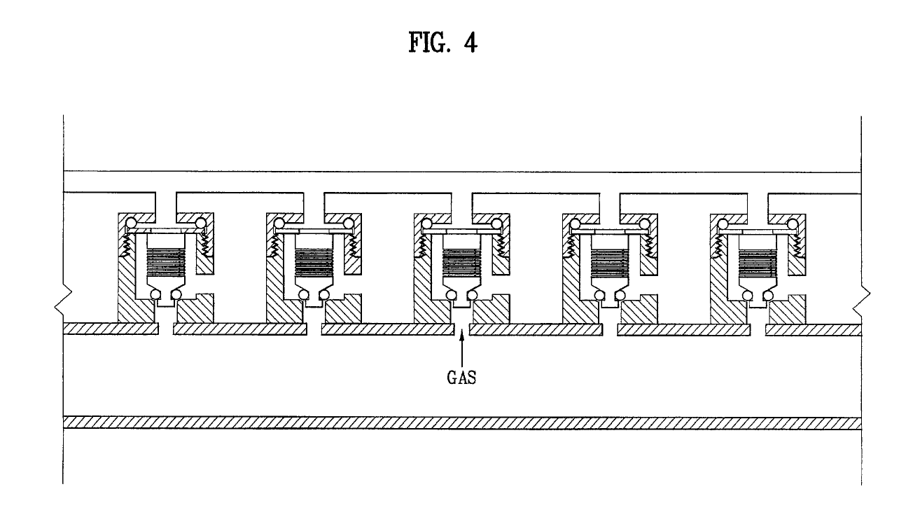

FIG. 4 is a schematic cross-sectional view of on/off valves connected in parallel. By using a plurality of on/off valves connected in parallel, the cesium vapor may be emitted to the feeding manifold 14 (shown in FIG. 1) in a stable condition.

A cesium vapor emitter may be retrofitted to any kind of sputter deposition apparatus, such as plasma sputter deposition apparatus, magnetron sputter deposition apparatus, hollow cathode magnetron sputter deposition apparatus, and ion beam sputter deposition apparatus.

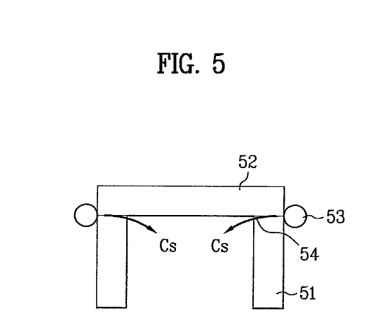

FIG. 5 is a schematic cross-sectional view of a sputter target of an apparatus for forming a thin film from a negatively charged sputtered ion according to a second embodiment of the present invention.

For simplicity, only a sputter target and a cesium vapor emitter are illustrated in FIG. 5. A detailed description for the cesium emitter is omitted because the same cesium emitter may also be used in the second embodiment.

As shown in FIG. 5, the sputter target has a shape suitable for hollow cathode magnetron sputter. In the second embodiment of the present invention, the sputter target includes a cylindrical target 51 and a planar target 52. The inside space of the cylindrical target 51 provides a hollow cathode effect. There is a channel between the cylindrical target 51 and the planar target 52, so that the cesium vapor is introduced through the channel from the feeding manifold 14 (shown in FIG. 1). The adsorbed cesium ions on the inside surface of the targets induce a generation of the negatively charged sputtered ions from the targets when the sputtering is in progress.

Unlike the neutral sputtered particle of the conventional sputtering, the negatively ionized sputtered particles in the present invention carries their kinetic energy to the substrate. When the energetic incident particle collides with a particle on the substrate, a metastable bonding is kinetically activated between the two different particles. For example, a thin film having an sp³ bonding cannot be formed by a thermal process.

In addition, when the energetic incident particles collide with the particles on the substrates, the energy of the incident particles is transferred to the other particles. This additional energy and increased mobility may result in a densification of the film, a strong adhesion to the substrate, and a smooth surface.

It will be apparent to those skilled in the art that various modifications and variations can be made in the apparatus and the method of forming thin film from negatively charged sputtered ions of the present invention without departing from the spirit or scope of the inventions. Thus, it is intended that the present invention covers the modifications and variations of this invention provided they come within the scope of the appended claims and their equivalents.

What is claimed is:

1. A cesium vapor emitter for inducing a plurality of negatively ionized sputtered particles from a sputter target, comprising:
a feeding manifold having a plurality of apertures therein and placed in close proximity to the sputter target to introduce cesium vapor onto a reacting surface of the target;
a reservoir coupled to the feeding manifold and filled with a cesium slurry; and
an on/off valve controlling an amount of the cesium vapor from the reservoir.

2. The cesium vapor emitter according to claim 1, wherein the emitter is capable of being retrofitted to one of sputter deposition apparatus, hollow cathode magnetron sputter deposition apparatus, and ion beam sputter deposition apparatus.

3. The cesium vapor emitter according to claim 1, wherein the feeding manifold has a shape substantially the same as the target.

4. The cesium vapor emitter according to claim 1, wherein the reservoir and the feeding manifold are heated at a temperature range of about 50 to 300° C.

5. The cesium vapor emitter according to claim 1, wherein the cesium slurry is a mixture of cesium mordenite powder and liquid cesium.

6. A sputter deposition apparatus for forming a thin film on a substrate, comprising:
at least one sputter target comprised of a material for the thin film;
an ion gun emitting a neutralized ion beam towards the sputter target;
a sputter gas source supplying a sputter gas into the ion gun; and
a cesium vapor emitter inducing a plurality of negatively ionized sputtered particles from the sputter target and located in close proximity to the sputter target to introduce cesium vapor onto a reaction surface, wherein the cesium vapor emitter includes a feeding manifold having a plurality of apertures therein, a reservoir coupled to the feeding manifold and filled with a cesium slurry, and an on/off valve controlling an amount of the cesium vapor from the reservoir.

7. The apparatus according to claim 6, further comprising a rotating target holder holding at least one sputter target.

8. The apparatus according to claim 6, wherein the feeding manifold has a shape substantially the same as the target.

9. The apparatus according to claim 6, wherein the reservoir and the feeding manifold are heated at a temperature range of about 50 to 300° C.

10. The apparatus according to claim 6, wherein the cesium slurry is a mixture of cesium mordenite powder and liquid cesium.

11. A sputter deposition apparatus for forming a thin film on a substrate, comprising:
an anode;
at least one sputter target comprised of a material for the thin film, electrically coupled to the anode, wherein the sputter target acts as a cathode and has a hollow region providing a directionality of sputtered particles from the sputter target towards the substrate;
a magnetic field source generating a magnetic field around the sputter target;
a cesium vapor emitter inducing a plurality of negatively ionized sputtered particles from the sputter target and located in close proximity onto surfaces of the wall in the sputter target to provide cesium vapor, wherein the cesium vapor emitter includes a feeding manifold having a plurality of apertures therein and surrounding the sputter target, a reservoir coupled to the feeding manifold and filled with a cesium slurry, and an on/off valve controlling an amount of the cesium vapor from the reservoir.

12. The apparatus according to claim 11, wherein the reservoir and the feeding manifold are heated at a temperature range of about 50 to 300° C.

13. The apparatus according to claim 11, wherein the cesium slurry is a mixture of cesium mordenite powder 50%-liquid cesium 50% by weight.

14. The apparatus according to claim 11, wherein the sputter target includes a planar target and a cylindrical target and a channel between the planar and cylindrical targets.

15. The apparatus according to claim 14, wherein the cesium vapor is introduced through a channel from the cesium vapor emitter.

16. A method of forming a thin film on a substrate using a negatively ionized sputter beam, the method comprising:
emitting cesium vapor from a cesium vapor emitter onto a sputter target, wherein the cesium vapor emitter includes a cesium feeding manifold located in close proximity to the target and a cesium reservoir filled with a cesium slurry and coupled to the cesium feeding manifold;
introducing a sputter gas source into an ion gun facing into the sputter target;
producing an ion beam from the ion gun onto the sputter target;
initiating a surface ionization with help of cesium on the target;
producing a plurality of negatively ionized sputtered particles from the sputter target; and
forming the thin film on the substrate by depositing the negatively ionized sputtered particles on the substrate.

17. A method of forming a thin film on a substrate using a negatively ionized sputter beam, the method comprising:
generating a magnetic field at an inside surface of a hollow region in a sputter target;
emitting cesium vapor from a cesium vapor emitter onto the inside surface of the sputter target, wherein the cesium vapor emitter includes a cesium feeding manifold located in close proximity to the target and a cesium reservoir filled with a cesium slurry and coupled to the cesium feeding manifold;
producing a plurality of negatively ionized sputtered particles from the sputter target; and
forming the thin film on the substrate by depositing the negatively ionized sputtered particles on the substrate.
